(19) United States
(12) Patent Application Publication
(10) Pub. No.: US 2011/0104381 A1
(43) Pub. Date: May 5, 2011

(54) Plasma Treatment of Large-Scale Components

(76) Inventor: Stefan Laure, Stuttgart (DE)

(21) Appl. No.: 10/586,009

(22) PCT Filed: Jun. 21, 2004
(86) PCT No.: PCT/DE2005/000047

§ 371 Date: Nov. 19, 2010

(30) Foreign Application Priority Data
Jan. 15, 2004 (DE) 10 2004 002 878.8

(51) Int. Cl. H05H 1/24; C23C 16/00; C23C 4/12; C23C 16/50

(52) U.S. Cl. 427/446; 118/723 R; 427/569

(57) ABSTRACT

The invention relates to a device and a method for the plasma treatment of large-scale components. Said device comprises a vacuum chamber (3) containing one or more pumps, a transport device (2) for conveying the component (1) into the vacuum chamber (3), insulation (4) that is situated between the component (1) and the vacuum chamber (3), a resonant circuit comprising a high-frequency generator (5), an adjustable capacitance and an adjustable inductance of the resonant circuit and at least one connection for connecting the resonant circuit to the component (1). To carry out said method, the component (1) is placed in the vacuum chamber (3), the latter is evacuated, the component (1) is connected to the resonant circuit comprising the high-frequency generator (5) and the inductance and/or the capacitance of the resonant circuit is tuned to the component (1).

This invention relates to a device and a method for the plasma treatment of large-volume components by means of a high-frequency electromagnetic field.

If the surface of a component is exposed to a plasma, the functionality and the characteristics of the surface can be selectively affected and modified by appropriate selection of the plasma parameters such as pressure, temperature and plasma composition. Processes in which the particle or energy currents from the plasma are utilized for the treatment, modification or coating of a surface of a wide range of materials are known from the prior art. These processes include, among others, plasma spraying, plasma arc melting, plasma heat treatment processes, plasma CVD (Chemical Vapor Deposition) processes and plasma cleaning. The modification in the functionality of workpiece surfaces is the result of the targeted attack of plasma particles. This modification can be achieved by the interaction with particles with certain chemical characteristics or by the action of radiation emitted by the plasma.

A plasma torch is used for generating a plasma. With a plasma arc torch, the gas flow is ionized by an arc and heated to temperatures from 10,000 to 20,000 K. With the high-frequency plasma torch, the gas flow is ionized by applying a high-frequency electromagnetic field to a cylindrical coil. A relatively dense plasma with high energy density is created in a cylindrical discharge tube which is manufactured from a dielectric material. Here too, plasma temperatures of up to 20,000 K are achieved.

The thermal plasmas described above are suitable for treating components that are characterized by specific temperature stability. Such processes cannot be used with plastic components or components that have been painted, which can only be exposed to temperatures that do not exceed 100-200° C.

High-frequency generators are also used for producing thin plasmas with relatively low energy densities. Their frequency range lies between a few hundred kilohertz up to several tens of GHz. The plasma is generated as a source on the surfaces of electrodes or antennae and expands across the space. As the distance from the electrode increases, both the composition of the plasma and the intensity of the radiation emitted by the plasma change.

While such plasma treatment is suitable for use on small components, however, it is not suitable for use on large components. The plasma only occurs in a very limited area and does thus not develop across the entire component. For plasma treatment of the entire surface of a large component, the plasma jet must therefore be directed across the component. In the case of components such as automobile bodies, this type of treatment is time-consuming and expensive.

Moreover, the methods of the prior art are not suitable for the treatment of the gaps, joints, cavities and undercuts that are found on automobile bodies. Surfaces that are facing away from the plasma source are not exposed to uniform plasma coverage. Due to the large gradients, uniform processing cannot be ensured on the surfaces facing the plasma source. This limitation applies in particular to processing steps that are dominated by radiation processes.

In contrast, the device taught by the invention with the features of claim 1 and the method taught by the invention with the features of claim 6 has the advantage that large components can be subjected to consistently effective plasma treatment across their entire surface. This treatment includes both interior and exterior surfaces. Gaps, joints, cavities and undercuts can also be processed. Such areas are found in particular on components which consist of multiple elements.

The device taught by the invention and the method taught by the invention can be used with any components of various sizes. They are particularly suitable for use on large components such as vehicle bodies, aircraft and machine parts, to cite only a few examples. A prerequisite in this case is that the vacuum chamber must be adequately sized and the transport device must be suitable for use with the component.

The component is introduced into a vacuum chamber of the device for plasma treatment. The component is then connected to a resonant circuit with a high-frequency generator. For this purpose, either one terminal or two terminals of the resonant circuit are connected to the component. In the first case, the second terminal is connected to ground. Consequently, the component forms a part of the resonant circuit. The high-frequency alternating current flows through the component. In this instance, the inductance and the capacitance of the component affect the inductance and the capacitance of the resonant circuit. The resonant circuit, which is comprised of the component to be processed and its own capacitances and inductances, must be appropriately adjusted to ensure the optimal coupling of the electrical energy to the component. This adjustment is accomplished by variation of the capacitances and inductances of the resonant circuit. The capacitances and inductances of the resonant circuit can be adjusted either manually or automatically. For automatic adjustment, first the capacitance and the inductance of the component are determined. The variation of the capacitances and inductances of the resonant circuit results in a change of the frequency.

Using the device and methods inherent to the invention, different treatments for the component are possible. A chemical treatment of the component surface can be performed by the chemical action of the plasma particles. The physical characteristics of the surface can be affected by the plasma radiation. This includes cross-linking of UV varnishes, for instance. As a result of the surface discharges, electrical effects occur on the surface which can be used for its treatment.

In contrast to electrode arrays, the distance of the electrodes from the component does not have to be adjusted. The plasma is generated through the formation of eddy currents on the surface of the component.

The alternating current flowing through the component induces oscillating magnetic fields which propagate in the vicinity of the component as a function of the geometry of the component. The change of the magnetic field over time results in electrical fields which are responsible for the generation and maintenance of the plasma in the vicinity of the component.

In one advantageous development of the invention, the transport device for introducing the component into the vacuum chamber comprises one or more rails and a drive system. In this instance, the rails can be adapted to the component. Electrical isolation is provided on the rails or in the vicinity of the rails to isolate the component with respect to the vacuum chamber.

In a further advantageous development of the invention, the resonant circuit comprises high-frequency lines. Bushings with electrical isolation for the high-frequency lines are provided on the vacuum chamber.

In a further advantageous development of the invention, metal plates, pipes and/or grids are provided. The component represents an antenna, from which electromagnetic waves are radiated into the space of the vacuum chamber. This effect can be promoted by further antenna-like elements in the vicinity of the component. These elements can include metal plates or grids. This effect can also be produced by pipes made of copper which are arranged in the form of a spiral. The electromagnetic waves couple into these parts and ensure additional plasma generation at a certain distance from the component. In this manner, the radiant flux of the plasma toward the component can be controlled.

In a further advantageous development of the invention, an industrial gas is introduced into the vacuum chamber. In this manner, the pressure in the vacuum chamber can be increased. This pressure can be up to 1000 Pa, for example. The industrial gas interacts chemically with the surface of the component. A number of different gases can be used as industrial gases, depending on the requirement.

In a further advantageous development of the invention, a liquid is vaporized and introduced into the vacuum chamber through a valve. The vapor from the liquid performs the same task as the industrial gases.

In accordance to a further advantageous development of the invention, an alternating voltage at 0.8 to 10 MHz is fed into the resonant circuit via the high-frequency generator. Particular preference is given to an alternating voltage between 1 and 4 MHz.

In a further advantageous development of the invention, the vacuum chamber is evacuated to a pressure between 0.05 and 0.5 Pa. In contrast to the methods of the prior art, the working pressure can be increased to several tens of mbars, depending on the application. In this way, a further resource can be made available to control the number of particles that interact with the surface of the component to be treated. When industrial gases are used, the pressure in the chamber is significantly higher.

Further advantages and advantageous developments of the invention can be found in the following specifications, the accompanying drawings and the claims.

One exemplary embodiment of a device for plasma treatment taught by the invention is explained in greater detail below and illustrated in the accompanying figures, which show:

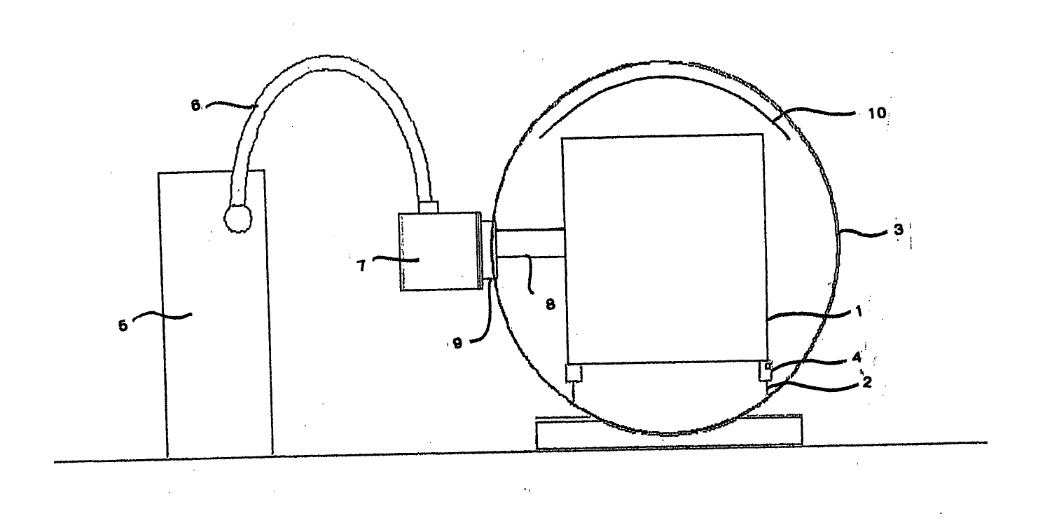

FIG. 1 Device for plasma treatment, viewed from the front,

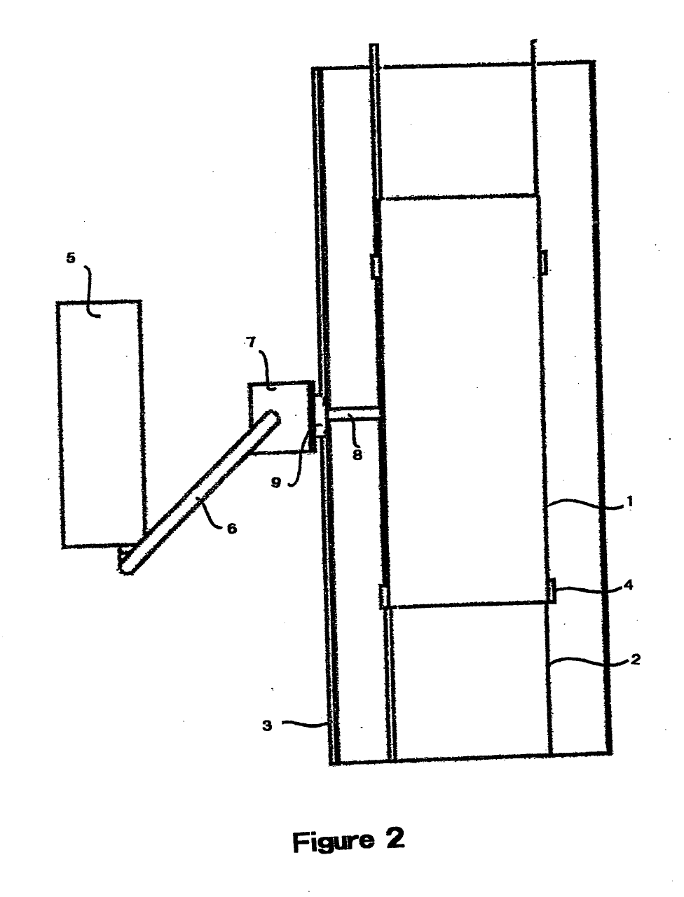

FIG. 2 Device for plasma treatment, viewed from the top,

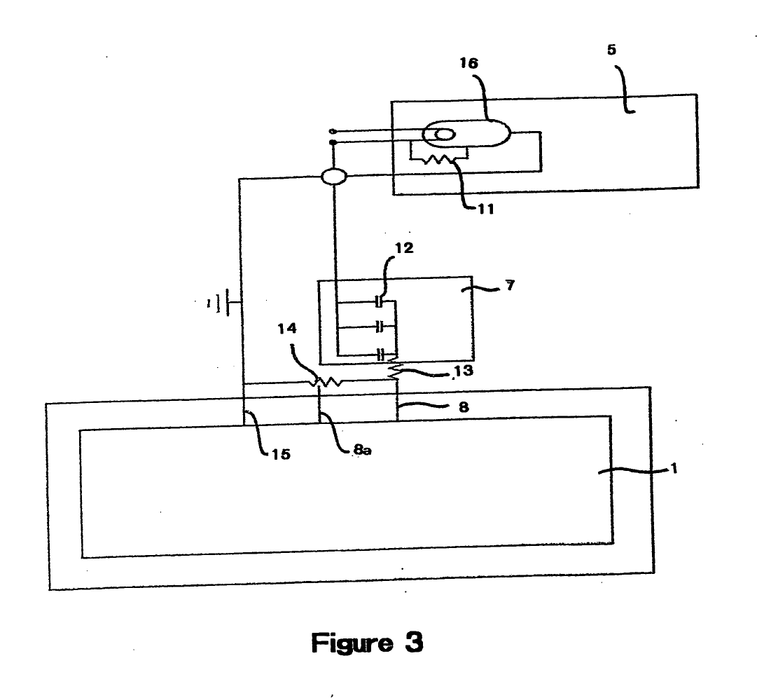

FIG. 3 Circuit diagram for the device according to FIGS. 1 and 2.

FIGS. 1 and 2 show a device for plasma treatment, viewed from the front and from the top. A component 1 to be treated is driven into a vacuum chamber 3 via rails 2 and rollers which are not discernible in the drawing. Rails 2 are provided with isolation 4, which isolates the component 1 with respect to the vacuum chamber 3. Once it has arrived at its terminal position, contact is made between a high-frequency resonant circuit and the component. This contact is made by means of a sliding contact which is not discernible in the drawing and adheres to the component 1 by means of an interlocking fit. The component is now part of the resonant circuit. Apart from component 1, the resonant circuit is comprised of a high-frequency generator 5 with a feedback coil 11, shown in FIG. 3, a coaxial cable 6, an external resonant circuit 7 and a high-frequency feed 8 which has a sliding contact on its ends. A high-frequency bushing 9 is provided for the high-frequency feed 8 in the vacuum chamber 3. A reflector 10 for the plasma is provided above the component.

FIG. 3 shows a schematic circuit diagram of the device illustrated in FIGS. 1 and 2. The circuitry makes possible the optimization of the plasma treatment. The high-frequency generator 5 supplies alternating current to the resonant circuit via a coaxial cable 6. The high-frequency generator 5 has a feedback coil 11, in which the inductance can be automatically adjusted. Three capacitors 12 are provided in the external resonant circuit 7. They can be either all or partially integrated in the resonant circuit to vary the overall capacitance. The inductance of the resonant circuit is essentially determined by component 1. Component 1 is connected to the external resonant circuit 7 via the high-frequency feed 8. To tune the inductance of the resonant circuit to the component, a coil 13 is provided on the external resonant circuit. In addition, a further coil 14 with a tap on the high-frequency feed 8 is provided directly on coil 13. This coil is integrated into the resonant circuit only if so required for the adjustment of the overall inductance. In this case, the high-frequency feed 8a is then used instead of the high-frequency feed 8. The component 1 can be optionally grounded via ground conductor 15.

The contact between component 1 and the resonant circuit can be checked by feeding a high-frequency alternating current at very low power. If the contact meets the requirements, the vacuum chamber 3 is evacuated. After the pressure in the vacuum chamber 3 has reached a certain value which depends on the type of treatment, high-frequency alternating current is fed into the resonant circuit. The plasma which is required for the treatment of the component is formed on the surface of component 1. The influence of the plasma on the surface of the component is controlled by adjusting the anode voltage of a transmitting tube 16 which feeds the alternating current into the resonant circuit. The transmitting tube is not shown in the drawing. The efficiency of the coupling of the electric power into the plasma can be monitored by monitoring the current/voltage characteristic curve of the transmitting tube 16 of the resonant circuit. The fine-tuning of the resonant circuit during the plasma treatment is through variation of the inductance of the feedback coil of the resonant circuit. In addition, a rough adjustment of the system to the component to be treated can be made by inserting additional inductances 14 or capacitances 12 into the resonant circuit. After the plasma treatment, the vacuum chamber 3 is restored to atmospheric pressure. The contact to the resonant circuit is broken and the component 1 is transported out of the vacuum chamber 3.

### REFERENCE NUMBERS

1 Component
2 Rail
3 Vacuum chamber
4 Isolation
5 High-frequency generator
6 Coaxial cable
7 External resonant circuit
8 High-frequency feed
9 High-frequency bushing
10 Reflector
11 Feedback coil
12 Capacitor of the external resonant circuit
13 Coil
14 Coil
15 Ground line
16 Transmitting tube

1. Device for plasma treatment of large-volume components with a vacuum chamber (3), with one or more pumps, with a transport device (2) for conveying the component (1) into the vacuum chamber (3),
with isolation (4) between the component (1) and the vacuum chamber (3),
with a resonant circuit with a high-frequency generator (5),
with an adjustable capacitance and an adjustable inductance of the resonant circuit,
with at least one terminal for connecting the resonant circuit with the component (1).

2. Device according to claim 1, wherein the transport device comprises one or more rails (2) and a drive system.

3. Device according to claim 2, wherein the rails (2) comprise electrical isolation (4) which isolates the component (1) with respect to the vacuum chamber (3).

4. Device according to claim 1, 2 or 3, wherein the resonant circuit comprises one or multiple high-frequency lines (8) and that the vacuum chamber (3) is provided with high-frequency bushings (9) with electrical isolation for the high-frequency lines.

5. Device according to one of the preceding claims, wherein the vacuum chamber (3) is provided with metal plates (10) and/or grids.

6. Device according to one of the preceding claims, wherein the high-frequency generator (5) comprises a feedback coil (11) with adjustable inductance.

7. Device according to one of the preceding claims, wherein switches are provided for capacitances (12) and/or inductances (14) which are connected with the resonant circuit to tune the capacitance and/or the inductance of the resonant circuit to the component (1).

8. Device according to one of the preceding claims, wherein a transmitting tube (16) for feeding the alternating current into the resonant circuit is provided.

9. Method for plasma treatment of large-volume components, in particular by using a device according to one of the preceding claims, wherein
the component (1) is positioned in a vacuum chamber (3) and the vacuum chamber is evacuated,
the component (1) is connected to a resonant circuit with a high-frequency generator (5), that the inductance and/or the capacitance of the resonant circuit is tuned to the component (1).

10. Method according to claim 9, wherein the contact between the component (1) and the resonant circuit is monitored by feeding a high-frequency alternating current at low power into the resonant circuit.

11. Method according to claim 9 or 10, wherein an industrial gas is fed into the vacuum chamber (3).

12. Method according to claim 9 or 10, wherein a liquid is vaporized and fed into the vacuum chamber through a valve.

13. Method according to one of claims 9 through 12, characterized in that an alternating voltage at 0.8 to 10 MHz is fed into the resonant circuit via the high-frequency generator (5).

14. Method according to one of claims 9 through 13, wherein the vacuum chamber (3) is evacuated to a pressure between 0.05 and 0.5 Pa.

15. Method according to one of claims 9 through 14, wherein panels (10) and/or grids are positioned in the vacuum chamber (3).

16. Method according to one of claims 9 through 15, wherein the plasma on the surface of the component (1) is adjusted by variation of the anode voltage of a transmitting tube which feeds the alternating current into the resonant circuit.

17. Method according to one of the claims 9 through 16, wherein additional capacitances (12) and/or inductances (14) in the resonant circuit are used for the rough tuning of the resonant circuit to the component (1).

18. Method according to one of claims 9 through 17, wherein the inductance of the feedback coil (11) of the resonant circuit is varied for the fine-tuning of the resonant circuit to the component (1).

19. Method according to one of claims 9 through 18, wherein the inductance and the capacitance of the component (1) are determined, and the inductance and the capacitance of the resonant circuit are adjusted to the inductance and capacitance of the component.
